(19) United States
(12) Patent Application Publication
(10) Pub. No.: US 2026/0255695 A1
(43) Pub. Date: Aug. 27, 2026

(54) PHOTOVOLTAIC MODULE

(71) Applicant: COLORADO STATE UNIVERSITY RESEARCH FOUNDATION, Fort Collins, CO (US)

(72) Inventors: Ryan Ruhle, Fort Collins, CO (US); Walajabad Sampath, Fort Collins, CO (US); David Durney, Fort Collins, CO (US); Larry Maple, Fort Collins, CO (US)

(21) Appl. No.: 19/160,262

(22) PCT Filed: Feb. 29, 2024
(86) PCT No.: PCT/US2024/017863

§ 371 Date: Aug. 27, 2025

Related U.S. Application Data
(60) Provisional application No. 63/449,068, filed on Mar. 1, 2023.

(51) Int. Cl. H10F 19/80; H10F 77/40; H10F 77/70

(52) U.S. Cl. CPC H10F 19/807; H10F 19/804; H10F 77/413; H10F 77/703; H10F 77/707

(57) ABSTRACT

Various implementations include a photovoltaic (PV) module. The PV module includes a PV cell and a transparent layer. The PV cell has a first side and second side opposite and spaced apart from the first side of the PV cell. The first side is configured to absorb light. The transparent layer has a first side and a second side opposite and spaced apart from the first side of the transparent layer. The second side of the transparent layer is adjacent to and spaced apart from the first side of the PV cell to define a gap.

### CROSS-REFERENCE TO RELATED APPLICATIONS

This application is a national stage application filed under 35 U.S.C. § 371 of PCT/US 2024/017863 filed Feb. 29, 2024, which claims the benefit of U.S. Provisional Patent Application No. 63/449,068, filed Mar. 1, 2023, the contents of which are incorporated herein by reference in their entirety.

### STATEMENT REGARDING FEDERALLY SPONSORED RESEARCH OR DEVELOPMENT

This invention was made with government support under grant 2052735 awarded by the National Science Foundation. The government has certain rights in the invention.

### BACKGROUND

Solar panel manufacturing plays a vital role in creating sustainable energy solutions for the future. Reducing manufacturing costs and capital expenditures will improve the competitiveness of the production of solar panels. The solar panel recycling industry plays a vital role in promoting the principles of the circular economy, which aims to maximize the value and lifespan of resources by reducing waste, reusing materials, and recycling components to create a closed-loop system. In solar panel recycling, the industry focuses on extracting valuable materials from end-of-life solar panels and reintroducing them into production. This approach helps minimize reliance on virgin resources. It reduces the environmental impact associated with extracting and manufacturing new materials.

Solar panels contain various components, including silicon wafers, metals, glass, and plastics. These components can be recovered and processed through advanced recycling technologies so that they can be reused in manufacturing new solar panels or other products. This approach conserves resources and reduces the amount of waste in landfills.

Several existing technologies are used for recycling solar panels. Mechanical processes shred and grind panels to separate glass, silicon cells, and metals. Thermal processes, like pyrolysis, use high temperatures to decompose panels into gases and solid residues. Chemical processes dissolve components using solutions like acid leaching. Electrochemical methods utilize electricity to extract metals. Silicon reclamation focuses on reclaiming and purifying silicon wafers. The technologies used in the existing recycling techniques vary based on panel type and composition.

The solar panel recycling industry also addresses the proper disposal of hazardous materials found in solar panels, such as lead and cadmium. The industry protects human health and the environment by adhering to strict regulations and employing safe handling practices.

However, the current recycling techniques are often cost prohibitive or disincentivizing. The current recycling cost for c-Si modules is around $45, while disposal costs range from $5 to $9. This economic disparity incentivizes panel disposal rather than recycling.

Thus, there is a need for the enabling of the separation of module materials without costly mechanical, thermal, and chemical processes.

### SUMMARY

Various implementations include a photovoltaic (PV) module. The PV module includes a PV cell and a transparent layer. The PV cell has a first side and second side opposite and spaced apart from the first side of the PV cell. The first side is configured to absorb light. The transparent layer has a first side and a second side opposite and spaced apart from the first side of the transparent layer. The second side of the transparent layer is adjacent to and spaced apart from the first side of the PV cell to define a gap.

In some implementations, the transparent layer includes glass.

In some implementations, the gap includes a gas gap. In some implementations, the gas gap includes an inert gas. In some implementations, the gas gap includes air.

In some implementations, the first side of the PV cell includes a first textured surface, and the second side of the transparent layer includes a second textured surface. In some implementations, the first textured surface, the second textured surface, or both includes an acrylic polymer. In some implementations, the second textured surface includes silicon dioxide. In some implementations, the first textured surface or the second textured surface includes a moth-eye structure. In some implementations, the first textured surface includes nanostructured acrylic.

In some implementations, the PV cell includes a c-Si PV cell.

In some implementations, the PV cell includes a bottom layer having a first side and a second side opposite and spaced apart from the first side of the bottom layer. In some implementations, the first side of the bottom layer is coupled to the second side of the transparent layer by a seal to form a water-tight cavity. In some implementations, the PV cell is disposed within the cavity.

In some implementations, the transparent layer is a first transparent layer, and the bottom layer is a second transparent layer. In some implementations, the second transparent layer includes glass.

In some implementations, the seal comprises polyisobutylene (PIB). In some implementations, the seal includes a first layer of PIB and a second layer of PIB spaced apart from the first layer of PIB to form a seal gap. in some implementations, the first layer of PIB is closer to a perimetrical edge of the transparent layer than the second layer of PIB is to the perimetrical edge of the transparent layer. In some implementations, the seal further includes a desiccant disposed within the seal gap.

In some implementations, the cavity is an air-tight cavity. In some implementations, the seal includes silicone.

In some implementations, the first side of the bottom layer is spaced apart from the second side of the transparent layer by a spacer. In some implementations, the spacer includes a desiccant.

In some implementations, the PV cell includes one or more electrical leads extending from the PV cell, through the seal, and external to the PV module.

### BRIEF DESCRIPTION OF DRAWINGS

Example features and implementations of the present disclosure are disclosed in the accompanying drawings. However, the present disclosure is not limited to the precise arrangements and instrumentalities shown. Similar elements in different implementations are designated using the same reference numerals.

FIG. 1A is a perspective, exploded view of a prior art PV module.

FIG. 1B is a perspective, exploded view of a PV module, according to one implementation.

FIG. 2 is a detail perspective, exploded view of the PV module of FIG. 1B.

FIG. 3A is a cross-sectional view of the PV module of FIG. 1B.

FIG. 3B is a cross-sectional view of the prior art PV module of FIG. 1A.

FIG. 4 is a detail cross-sectional view of the seal of the PV module of FIG. 1B.

FIG. 5 is a cross-sectional view of a PV module, according to another implementation.

FIGS. 6A-6E are top views of the steps of manufacturing the PV module of FIG. 1B.

### DETAILED DESCRIPTION

The devices, systems, and methods disclosed herein provide for a modular approach to photovoltaic (PV) module architecture that aims to reduce capital expenditure, reduce material costs, improve reliability, and enhance recyclability. The architecture utilizes a perimeter seal instead of vacuum lamination, adapted explicitly for crystalline silicon (c-Si) and similar modules.

The architecture facilitates simple and automated processes for effective separation into constituent parts without the use of costly chemical processes by forgoing the vacuum lamination process with c-Si PV modules. The modules can include a layer of glass facing the sun (top glass) that is spaced apart from the PV cell. The gap between the top glass and PV cell can be sealed from moisture and air to protect the delicate PV cell. Because an encapsulant (such as EVA) does not need to be vacuum laminated to the PV cell like in traditional PV modules, the PV module components can be easily separated.

To seal the PV module to protect the PV cell from moisture and air, the devices, systems, and methods disclosed herein can utilize a double edge seal for PV devices which will protect PV circuit plates which are more susceptible to moisture than typical c-Si. The devices, systems, and methods disclosed herein can include two layers of low-iron tempered glass with a c-Si wafer. The glass facing the sun (top glass) is sealed with silicone, inside which polyisobutylene (PIB) is placed. Two PIB layers allow wire connections to exit from the side, enabling a side-mounted junction box instead of the traditional back box. The c-Si module is secured with a silicone-based adhesive along the power-transmitting wires, eliminating the need for conventional encapsulants and ensuring stability.

Research has shown that an air gap with desiccant can significantly improve a module's resilience against moisture ingress. Solar devices such as perovskites and perovskite tandem devices (such as perovskite and c-Si or perovskite and Cadmium Telluride CdTe) often have significantly reduced performance due to moisture and oxygen ingress. By including two layers of edge seal with a desiccant in between, moisture and gasses which break through the outer seal layer can be absorbed before there is a chance for them to penetrate the inner seal layer and impact the solar cells on the interior of the module. Desiccant and/or oxygen scavengers can be included to reduce the amount of moisture reaching the PV cell. This architecture has been shown to improve the survivability of the module devices with a reduced production time.

However, excluding an EVA, polyolefin (POE), or other encapsulant laminate layer and including a gap between the top glass and the PV cell can introduce inefficiencies due to increase in the overall reflectance. The devices, systems, and methods disclosed herein utilize texturing of the inwardly facing surface of the top glass and the top glass facing surface of the PV cell. The texture is optimized to improve the optical interface between the inert gas and cell and the glass and inert gas (or interior of the module). This helps reduce the mismatch of indices of refraction. The refractive index matching can be achieved by including surfaces that mimic a moth's eye efficiency to enhance optical transmission. The module's air gap or inert gas environment is ideal.

The top layer of the c-Si device can be more aggressively textured and can incorporate a Silicon Oxide layer for improved efficiency. It has been discovered that using textured coatings on the inwardly facing surface of the top glass and the outwardly facing surface of the c-Si module to achieve power matching. Utilizing air or inert gas significantly reduces recycling costs compared to material recovery, lowers manufacturing expenses, and decreases material costs in PV manufacturing.

EVA has a higher absorption of light than the air or inert gases present in the gap between the top glass and PV cell of the presently disclosed PV modules. This may further reduce differences in efficiencies between traditional PV modules and the PV modules disclosed herein.

Furthermore, the devices and systems disclosed herein require a smaller manufacturing footprint than existing PV modules that utilize EVA encapsulant lamination and require less manufacturing costs. The PV modules disclosed herein also require a lower material cost than existing PV modules.

The PV devices and systems disclosed herein also provide for better mechanical strength than existing PV modules, less moisture ingress than traditionally encapsulated PV modules, and less effects from glass temper distortion than traditional PV modules. Furthermore, the PV modules disclosed herein do not suffer from micro-cracking of the cells like PV modules that use EVA.

Overall, the devices, systems, and methods disclosed herein can achieve cost reduction, reliability improvement, and recyclability enhancement for c-Si PV modules by incorporating novel design elements to optimize performance and reduce environmental impact.

Various implementations include a photovoltaic (PV) module. The PV module includes a PV cell and a transparent layer. The PV cell has a first side and second side opposite and spaced apart from the first side of the PV cell. The first side is configured to absorb light. The transparent layer has a first side and a second side opposite and spaced apart from the first side of the transparent layer. The second side of the transparent layer is adjacent to and spaced apart from the first side of the PV cell to define a gap.

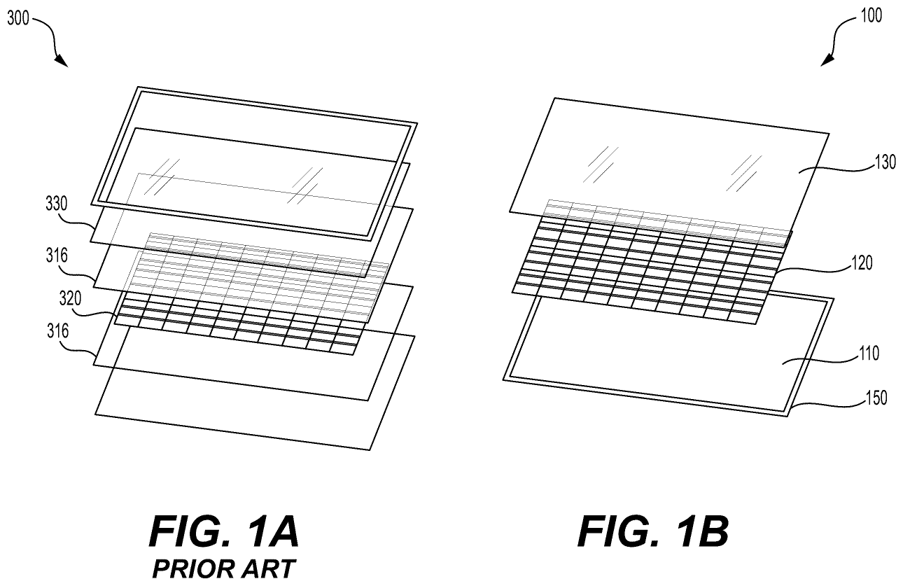

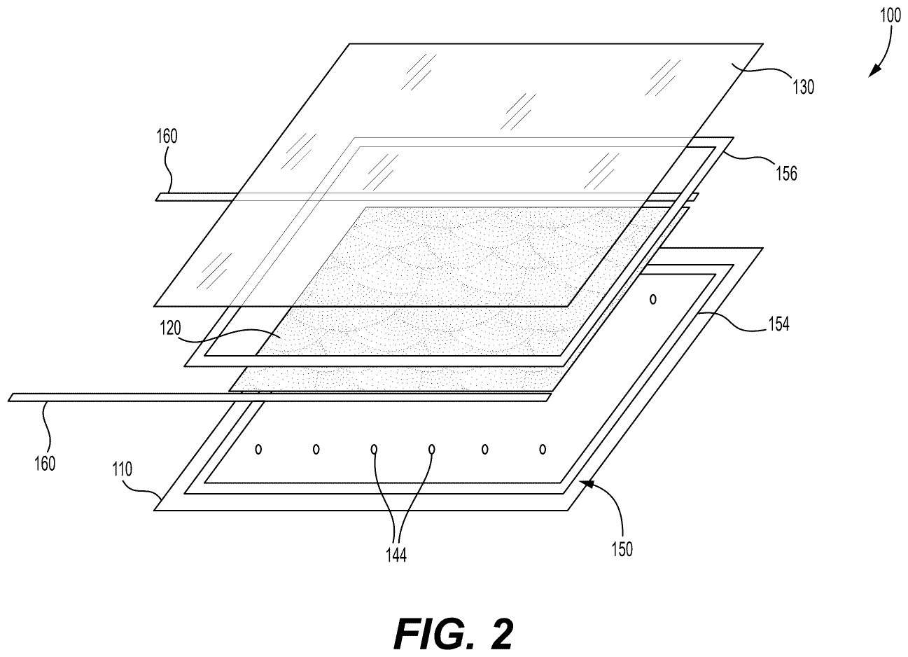

FIGS. 1B-3A and 4 show a PV module 100 according to one implementation. The PV module 100 includes a bottom glass layer 110, a PV cell 120, a top glass layer 130, and an edge seal 150. As used herein, the term “top glass” refers to the glass configured to face the sun, and the term “bottom glass” refers to the glass configured to face away from the sun.

The bottom glass layer 110 has a first side 112 and a second side 114 opposite and spaced apart from the first side 112 of the bottom glass layer 110. Although the bottom glass layer 110 shown in FIGS. 1B-3A and 4 is made of low-iron tempered glass, in some implementations, the bottom layer is made of any rigid transparent, translucent, or opaque material.

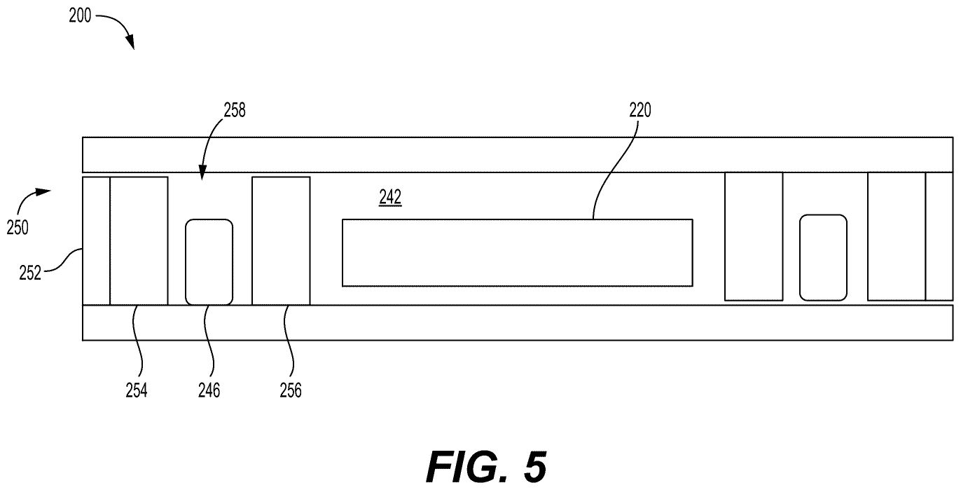

The PV cell 120 has a first side 122 configured to absorb light and a second side 124 opposite and spaced apart from the first side 122 of the PV cell 120. The PV cell 120 shown in FIGS. 1B-3A and 4 comprises a c-Si PV cell. However, in some implementations, the PV cell includes a perovskite PV cell 220 (see FIG. 5), multi-junction PV cells, or any other type of PV cell. In some implementations, the PV cell is bifacial and can absorb light from the first side and the second side to convert the light from both sides of the PV cell into electrical energy.

The second side 124 of the PV cell 120 is coupled to the bottom glass layer 110 by one or more small placements of a silicone-based adhesive 144 along the electrical wiring 160. The small amount of silicon-based adhesive 144 ensures that the PV cell 120 can be removed but is firmly held in place. While the placement and number of placements may vary by the architecture, one reason this retains recyclability is that the wires 160 can be removed from the bottom glass layer 110 prior to the PV cell 120 being removed from the wires 160. This allows for greater recovery of recyclable materials as the PV cell 120 is only attached to the wires 160 themselves.

The top glass layer 130 has a first side 132 and a second side 134 opposite and spaced apart from the first side 132 of the top glass layer 130. Although the top layer 130 shown in FIGS. 1B-3A and 4 is made of low-iron tempered glass, in some implementations, the top layer is made of any rigid transparent material.

One or more spacers 146 are coupled to the first side 112 of the bottom glass layer 110 outside the perimetrical edge of the PV cell 120 such that the one or more spacers 146 extend beyond the first side 122 of the PV cell 120. The top glass layer 130 is disposed such that the second side 134 of the top glass layer 130 abuts the one or more spacers 146 such that the second side 134 of the top glass layer 130 is spaced apart from the PV cell 120. Because the top glass layer 130 and the PV cell 120 are spaced apart from each other by the one or more spacers 146, a gap 140 is defined between the second side 134 of the top glass layer 130 and the first side 122 of the PV cell 120.

The first side 112 of the bottom glass layer 110 is coupled to the second side 134 of the top glass layer 130 by the seal 150 to form a water-tight and/or air-tight cavity 142 to protect the PV cell 120 from damage. The PV cell 120 is disposed within the cavity 142 such that the PV cell 120 is isolated from the outside environment.

In some implementations, the cavity is filled with a gas such as air or an inert gas such that the gap between the second side of the top glass layer and the first side of the PV cell is filled with the gas.

Providing a gap 140 between the top glass layer 130 and the PV cell 120 provides numerous benefits over the traditional EVA laminate PV modules, such as manufacturing cost reduction, manufacturing footprint reduction, material cost reduction, higher resistance against fracture, ability to handle greater loads, reliability improvement, and recyclability enhancement.

The perimeter seal 150 is included in the PV module 100 shown in FIGS. 1B-3A and 4 as opposed to a vacuum lamination process. The seal 150 includes silicone and polyisobutylene (PIB). The silicone 152 is disposed outwardly of the PIB 154, 156 to form a water-tight seal 150. This prevents liquids such as water from entering the cavity 142 and damaging the PV cell 120.

The PIB layer 154, 156 is disposed perimetrically inward of the silicon layer 152 to provide an air-tight seal 150. This prevents vapors such as water vapor from entering the cavity 142, which can also damage the PV cell 120. The PIB can be disposed in two layers 154, 156, one on top of the other. A bottom layer of PIB 154 can be disposed along the first side 112 of the bottom glass layer 120 prior to the placement of the PV cell 120. Once the PV cell 120 has been placed onto the bottom glass layer 110 such that the electrical leads 160 extend across the bottom PIB layer 154, a top layer of PIB 156 can be placed on top of the bottom PIB layer 154 and over the electrical leads 160. This ensures that, once the top glass layer 130 is placed onto the stacked PIB layers 154, 156 and pressed to compress the PIB layers 154, 156, a seal 150 is formed around the protruding electrical leads 160, as discussed in further detail herein.

The one or more spacers 146 shown in FIGS. 1B-3A and 4 are made of a desiccant material. The silicone layer 152 and PIB layers 154, 156 of the seal 150 are located perimetrically outward of the one or more spacers 146 such that the one or more spacers 146 are disposed within the cavity 142. Because the one or more spacers 146 include a desiccant, any moisture that is able to penetrate through the seal 150 is absorbed by the one or more spacers 146.

FIG. 5 shows another implementation of a PV module 200 similar to the PV module 100 of FIGS. 1B-3A and 4. However, the PV module 200 of FIG. 5 includes a different seal 250 configuration. The seal 250 of the PV module 200 shown in FIG. 5 includes a perimetrically outward silicone layer 252 and perimetrically inward PIB layer 254 similar to the PV module 100 of FIGS. 1B-3A and 4, but it also includes a second PIB layer 256 perimetrically inward and spaced apart from the first PIB layer 254. The space between the first PIB layer 254 and the second PIB layer 256 defines a seal gap 258. A desiccant material spacer 246 is disposed within the seal gap 258. The second PIB layer 256 ensures that, if moisture penetrates the silicone layer 252 and the first PIB layer 254, the moisture will be at least temporarily contained within the seal gap 258. While it is possible moisture within the seal gap 258 could further penetrate the second PIB layer 256 over time, the desiccant 246 is likely to absorb most of the moisture before it has time to penetrate through the second PIB layer 256 into the cavity 242. In effect, the second PIB layer 256 slows the ingress of moisture through the seal 250 long enough to allow the desiccant 246 to absorb the moisture, which leads to a longer lifespan of the PV cell 220 and PV module 200. The decrease in moisture ingress also reduces the impact of potential induced degradation (PID).

An air gap with desiccant can significantly improve a module's resilience against moisture ingress by adding a second layer of edge seal after the air gap to modules which utilize materials such as perovskites and perovskite tandem devices (such as perovskite and c-Si or perovskite and Cadmium Telluride CdTe). This improves survivability of these module devices with a reduced production time. New solar devices such as perovskites and perovskite tandem devices often have significantly reduced performance due to moisture and oxygen ingress. By including two layers of edge seal, moisture and gases which break through the outer layer of seal can be absorbed before there is a chance for them to impact the PV cells on the interior of the PV module.

The seal 250 of the PV module 200 provides for three time-delays: (1) a time-delay before the water-vapor penetrates through the outermost band, (2) a time-delay before all the desiccant strips become fully saturated, and (3) a time-delay before water-vapor finally penetrates through the innermost band and reaches the interior where it is available to attack the PV cell.

During the second time-delay (i.e., the desiccant time delay), most desiccants, such as zeolite, can keep the water vapor partial-pressure at or below ~1 milli-Torr. Hence, the innermost band of PIB would only be exposed to a very small change in water-vapor partial-pressure and would essentially allow no water-vapor to pass through it until the desiccant is totally consumed.

In some implementations, the first PIB layer and the second PIB layer have the same width as each other. In some implementations, the first PIB layer has a larger width than the second PIB layer. In some implementations, the second PIB layer has a larger width than the first PIB layer.

Although the seals 150, 250 in FIGS. 1B-3A, 4, and 5 include silicone, in some implementations, the seal can include any other material known to be capable of forming a fully or at least partially liquid or water-tight seal. Although the seals 150, 250 in FIGS. 1B-3A, 4, and 5 include PIB, in some implementations, the seal can include any other material known to be capable of forming a fully or at least partially air-tight seal. In some implementations, the seal can include any number of one or more liquid or water-tight seals and/or air-tight seals. In some implementations, any number of seal layers can be spaced apart from each other to form one or more seal gaps. For example, in some implementations, the module may include three PIB layers defining two seal gaps. In some implementations, desiccants and/or oxygen scavengers can be disposed within any number of the one or more seal gaps or anywhere else throughout the seal or module to absorb any additional elements which may be detrimental to the module.

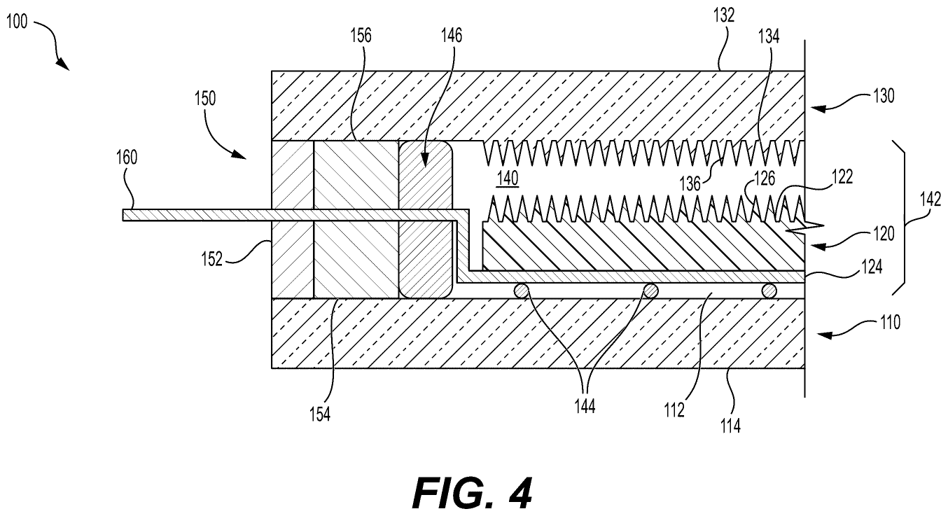

The PV module 100 shown in FIGS. 1B-3A and 4 further includes one or more busbar ribbons and/or electrical leads 160 in electrical communication with the PV cell 120. As shown in FIG. 4, the busbar 160 extends from the PV cell 120 through the seal 150 and beyond the perimetrical edges of the top glass layer 130 and the bottom glass layer 110. Because the busbar 160 extends through the seal 150, the seal 150 is able to form a liquid and air-tight seal 150 around the busbar 160 to ensure that moisture is not able to penetrate through the busbar opening and into the cavity 142.

In contrast, the busbars or other wiring of existing PV modules typically extend through the bottom glass layer and a separate seal is used to fill the opening in the glass around the busbar. These existing seals are prone to leaking and the holes through the glass are prone to failure, causing failure of the PV cell. However, since the busbar 160 of the PV modules 100 disclosed herein extend through the existing seal 150, which includes multiple layers, the opening is much better suited for preventing moisture inflow into the cavity 142.

The electrical leads 160 passing through the edge seal 150 of the PV module 100, rather than through the bottom of the PV module, can be vital for applications such as Building integrated Photovoltaics (BIPV) as well as agrivoltaics, where it is key to optimize light being transmitted through the PV module 100.

Furthermore, since the busbar and wiring 160 are relatively rigid, the PV cell 120 can be coupled only to the busbar and/or wiring 160, which is coupled to the bottom glass 110 by adhesive 144. This allows for give along the wires 160 and protects the PV cell 120 from additional stress and effects from heat transfer, thermal expansion, impact, and vibration.

Although the PV module 100 shown in FIGS. 1B-3A and 4 includes a busbar 160, in some implementations, the PV module can include any other type of electrical wiring, leads, or other means for transmitting electrical current from the PV cell to outside of the PV module.

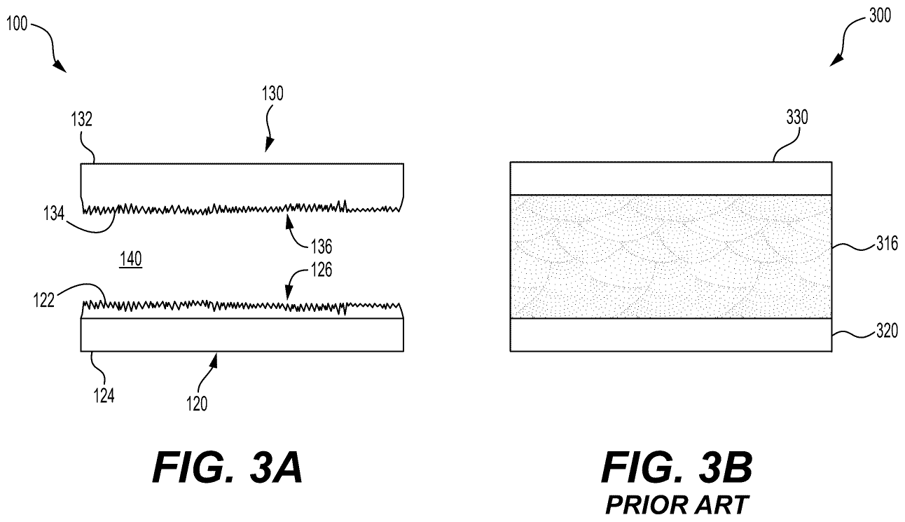

As shown in FIGS. 1A and 3B, many current PV modules 300 include an EVA lamination 316 over the PV cell 320. The EVA layer 316 provides a relatively low reflectance between the top glass 330 and the EVA 316, and between the EVA 316 and the PV cell 320. A lower reflectance typically results in a higher efficiency of light energy capture of the PV module 300.

The PV modules 100, 200 disclosed herein include a gap 140 between the top glass 130 and the PV cell 120, rather than including an EVA laminate layer 316. This provides many benefits such as ease of recyclability and lower manufacturing costs. However, the transition between the top glass layer 130 and the air gap 140, and between the air gap 140 and the PV cell 120, would typically create a relatively higher reflectance compared to the traditional EVA laminate modules 300.

To address this higher reflectance issue, the top glass layer 130 of the PV module 100 shown in FIGS. 1B-3A and 4 includes a textured surface 136 along the second side 134 of the top glass layer 130. Furthermore, the first side 122 of the PV cell 120 includes a textured surface 126. This “internal texture” of the surfaces still reflects light. However, rather than being reflected directly back into space by a relatively flat surface of the second side 134 of top glass 130 or the first side 122 of a PV cell 120, the incident light that enters the cavity 142 of the module 100 is reflected back into the cavity 142 by the textured surfaces 126, 136 of the second side 134 of the top glass layer 130 and of the first side 122 of the PV cell 120. Because the light within the module 100 can be reflected toward the PV cell 120 two or more times, the textured surfaces 126, 136 can provide the light with multiple chances at being absorbed and converted to electricity, increasing the overall efficiency of the PV module 100.

Lastly, EVA 316 has an absorption of greater than 1.5%, which decreases the efficiency of the PV module 300. In contrast, air or an inert gas within the cavity 142 of the PV modules 100 disclosed herein has negligible absorption. In total, given the greater absorption of the EVA than air and the increased efficiency of textured surfaces, research has shown that the PV modules 100 disclosed herein match the efficiency of, or have an efficiency higher than, traditional PV modules 300 despite the relatively lower reflectance between the layers of traditional PV modules 300.

The textured surfaces 126, 136 also significantly improve the convection on the interior of the PV module 100, which reduces the temperature mismatch relative to traditionally encapsulated PV modules 100.

The textured surface 136 of the second side 134 of the top glass layer 130 and the textured surface 126 of the first side 122 of the PV cell 120 are both made of acrylic polymers. However, in some implementations, only one of the textured surface of the second side of the top glass layer or the textured surface of the first side of the PV cell is made of acrylic polymers. In some implementations, neither of the textured surface of the second side of the top glass layer or the textured surface of the first side of the PV cell is made of acrylic polymers. In some implementations, one or both of the textured surface of the second side of the top glass layer or the textured surface of the first side of the PV cell is made of silicon dioxide. In some implementations, one or both of the textured surface of the second side of the top glass layer or the textured surface of the first side of the PV cell include a moth-eye structure. In some implementations, one or both of the textured surface of the second side of the top glass layer or the textured surface of the first side of the PV cell is made of nanostructured acrylic.

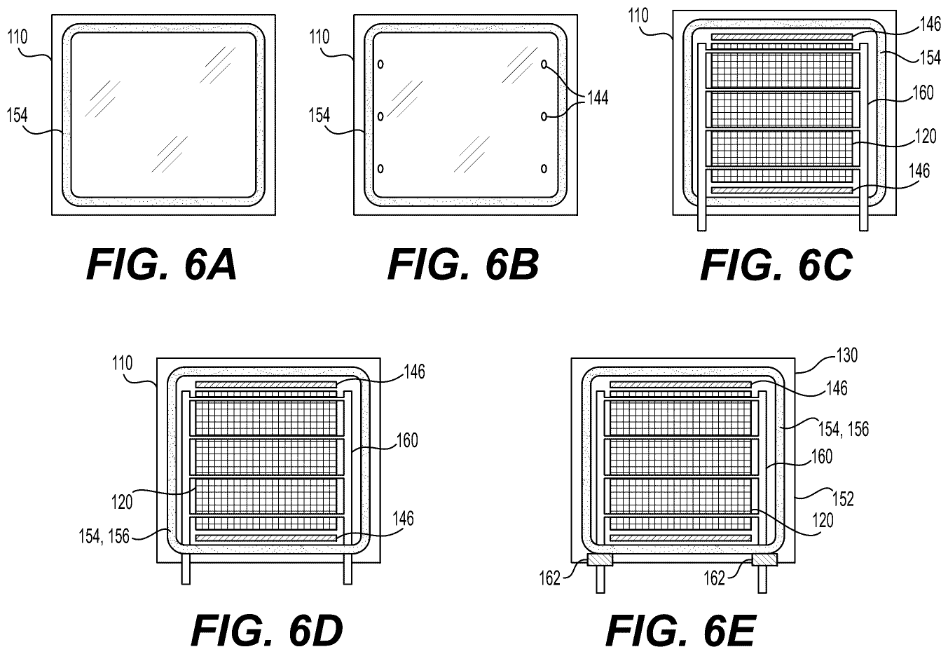

FIGS. 6A-6E shows the steps for manufacturing the PV module 100 shown in FIGS. 1B-3A and 4 and similar PV modules. FIG. 6A shows a first step of disposing a bottom layer of PIB 154 along a perimetrical edge of the bottom glass layer 110 to form a first seal. FIG. 6B shows another step of placing adhesive 144 along wiring paths for the PV cell 120. FIG. 6C shows a third step of placing the PV cell 120. The wires 160 of the PV cell 120 are aligned with the adhesive 144 on the bottom glass 110. Desiccant spacers are then added to the bottom glass layer 110 within the cavity 142. Note the electrical leads 160 extending across the bottom PIB layer 154. A top PIB layer 156 is placed along the top of the bottom PIB layer 154 and over the electrical leads 160. The combined height of the bottom and top PIB layers 154, 156 are at least as high as the desiccant spacers 146 such that the top glass layer 130 makes contact with the top PIB layer 156 prior to contacting the desiccant spacers 146. FIG. 6E shows a final step of placing the top glass layer 130 onto the top PIB layer 156 and pressing the top glass layer 130 until the top glass layer 130 contacts the desiccant spacers 146. A silicone seal layer 152 is then applied along the perimetrical edge of the PV module 100 adjacent the PIB layers 154, 156 and between the bottom glass layer 110 and the top glass layer 130. Clamping 162 can then be applied around the electrical leads 160 for a side junction box.

A number of example implementations are provided herein. However, it is understood that various modifications can be made without departing from the spirit and scope of the disclosure herein. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. Although the terms “comprising” and “including” have been used herein to describe various implementations, the terms “consisting essentially of” and “consisting of” can be used in place of “comprising” and “including” to provide for more specific implementations and are also disclosed.

Disclosed are materials, systems, devices, methods, compositions, and components that can be used for, can be used in conjunction with, can be used in preparation for, or are products of the disclosed methods, systems, and devices. These and other components are disclosed herein, and it is understood that when combinations, subsets, interactions, groups, etc. of these components are disclosed that while specific reference of each various individual and collective combinations and permutations of these components may not be explicitly disclosed, each is specifically contemplated and described herein. For example, if a device is disclosed and discussed each and every combination and permutation of the device are disclosed herein, and the modifications that are possible are specifically contemplated unless specifically indicated to the contrary. Likewise, any subset or combination of these is also specifically contemplated and disclosed. This concept applies to all aspects of this disclosure including, but not limited to, steps in methods using the disclosed systems or devices. Thus, if there are a variety of additional steps that can be performed, it is understood that each of these additional steps can be performed with any specific method steps or combination of method steps of the disclosed methods, and that each such combination or subset of combinations is specifically contemplated and should be considered disclosed.

What is claimed is:

1. A photovoltaic (PV) module, the PV module comprising:
a PV cell having a first side and second side opposite and spaced apart from the first side of the PV cell, wherein the first side is configured to absorb light; and
a transparent layer having a first side and a second side opposite and spaced apart from the first side of the transparent layer, wherein the second side of the transparent layer is adjacent to and spaced apart from the first side of the PV cell to define a gap.

2. The PV module of claim 1, wherein the transparent layer comprises glass.

3. The PV module of claim 1, wherein the gap comprises a gas gap.

4. The PV module of claim 3, wherein the gas gap comprises an inert gas.

5. The PV module of claim 3, wherein the gas gap comprises air.

6. The PV module of claim 1, wherein the first side of the PV cell includes a first textured surface, and the second side of the transparent layer includes a second textured surface.

7. The PV module of claim 6, wherein the first textured surface or the second textured surface comprises an acrylic polymer.

8. The PV module of claim 6, wherein the second textured surface comprises silicon dioxide.

9. The PV module of claim 6, wherein the first textured surface or the second textured surface comprises a moth-eye structure.

10. The PV module of claim 9, wherein the first textured surface comprises nanostructured acrylic.

11. The PV module of claim 1, wherein the PV cell comprises a c-Si PV cell.

12. The PV module of claim 1, wherein the PV cell comprises a perovskite PV cell.

13. The PV module of claim 1, wherein the PV cell comprises a c-Si perovskite tandem PV cell.

14. The PV module of claim 1, further comprising a bottom layer having a first side and a second side opposite and spaced apart from the first side of the bottom layer, wherein the first side of the bottom layer is coupled to the second side of the transparent layer by a seal to form a water-tight cavity, wherein the PV cell is disposed within the cavity.

15. The PV module of claim 14, wherein the transparent layer is a first transparent layer, and the bottom layer is a second transparent layer.

16. The PV module of claim 15, wherein the second transparent layer comprises glass.

17. The PV module of claim 14, wherein the seal comprises polyisobutylene (PIB).

18. The PV module of claim 17, wherein the seal comprises a first layer of PIB and a second layer of PIB spaced apart from the first layer of PIB to form a seal gap, wherein the first layer of PIB is closer to a perimetrical edge of the transparent layer than the second layer of PIB is to the perimetrical edge of the transparent layer.

19. The PV module of claim 18, wherein the seal further comprises a desiccant disposed within the seal gap.

20. The PV module of claim 14, wherein the cavity is an air-tight cavity.

21. The PV module of claim 20, wherein the seal comprises silicone.

22. The PV module of claim 14, wherein the first side of the bottom layer is spaced apart from the second side of the transparent layer by a spacer.

23. The PV module of claim 22, wherein the spacer comprises a desiccant.

24. The PV module of claim 14, further comprising one or more electrical leads extending from the PV cell, through the seal, and external to the PV module.
